(19) United States
(12) Patent Application Publication
(10) Pub. No.: US 2018/0275274 A1
(43) Pub. Date: Sep. 27, 2018

(54) HIGH RESOLUTION LIDAR USING MULTI-STAGE MULTI-PHASE SIGNAL MODULATION, INTEGRATION, SAMPLING, AND ANALYSIS

(71) Applicant: Innovusion Ireland Limited, Los Altos, CA (US)

(72) Inventors: Junwei BAO, Los Altos, CA (US); Yimin LI, Los Altos, CA (US)

(21) Appl. No.: 15/934,807

(22) Filed: Mar. 23, 2018

Related U.S. Application Data
(60) Provisional application No. 62/475,701, filed on Mar. 23, 2017.

(51) Int. Cl. G01S 17/10; G01S 7/486; H01L 27/146; G01S 17/89

(52) U.S. Cl. CPC G01S 17/10; G01S 17/89; H01L 27/14643; G01S 7/486

(57) ABSTRACT

The present disclosure describes techniques for implementing high resolution LiDAR using multiple-stage multiple-phase signal modulation, integration, sampling, and analysis technique. In one embodiment, a system includes a pulsed light source, one or more optional beam steering apparatus, an optional optical modulator, an optional imaging optics, a light detection with optional modulation capability, and a microprocessor. The optional beam steering apparatus is configured to steer a transmitted light pulse. A portion of the scattered or reflected light returns and optionally goes through a steering optics. An optional optical modulator modulates the returning light, going through the optional beam steering apparatus, and generates electrical signal on the detector with optional modulation. The signal from the detector can be optionally modulated on the amplifier before digitally sampled. One or multiple sampled integrated signals can be used together to determine time of flight, thus the distance, with robustness and reliability against system noise.

### CROSS-REFERENCE TO RELATED APPLICATIONS

This application claims priority to U.S. Provisional Patent Application Ser. No. 62/475,701, filed Mar. 23, 2017, entitled “HIGH RESOLUTION LIDAR USING MULTI-STAGE MULTI-PHASE SIGNAL MODULATION, INTEGRATION, SAMPLING, AND ANALYSIS”, the content of which is hereby incorporated by reference for all purposes.

### FIELD OF THE DISCLOSURE

The present disclosure generally relates to laser scanning and, more particularly, to systems and methods for obtaining high resolution object detection in the field-of-view using multi-stage signal modulation, integration, sampling, and analysis technologies.

### BACKGROUND OF THE DISCLOSURE

Light detection and ranging (LiDAR) systems use light signals (e.g., light pulses) to create a three-dimensional image or point cloud of the external environment. Some typical LiDAR systems include a light source, a signal steering system, and light detector. The light source generates pulse signals (also referred to herein as light pulses or pulses), which are directed by the signal steering system in particular directions when being transmitted from the LiDAR system. When a transmitted pulse signal is scattered by an object, some of the scattered light is returned to the LiDAR system as a returned pulse signal. The light detector detects the returned pulse signal. Using the time it took for the returned pulse to be detected after the pulse signal was transmitted and the speed of light, the LiDAR system can determine the distance to the object along the path of the transmitted light pulse. The signal steering system can direct light pulses along different paths to allow the LiDAR system to scan the surrounding environment and produce a three-dimensional image or point cloud. LiDAR systems can also use techniques other than time-of-flight and scanning to measure the surrounding environment.

### SUMMARY OF THE DISCLOSURE

The following disclosure presents a simplified summary of one or more examples in order to provide a basic understanding of the disclosure. This summary is not an extensive overview of all contemplated examples, and is not intended to either identify key or critical elements of all examples or delineate the scope of any or all examples. Its purpose is to present some concepts of one or more examples in a simplified form as a prelude to the more detailed description that is presented below.

In some embodiments, the present disclosure includes methods and systems that can provide multi-stage multi-phase signal modulation. A received light pulse can be modulated in one or more of the following stages in the signal processing pipeline: optical modulation before the light pulse enters the collection objective lens; gain modulation in the optical-to-electrical signal convertor (e.g., the optical detector); amplification modulation in the analog signal amplification stage.

In some embodiments, the present disclosure includes methods and systems that can integrate the output signal of the amplification stage, and sample the integrated one or multiple times during the expected pulse return period.

In some embodiments, the signal modulation and integration can be performed for one pulse or for a plurality of pulses (e.g., at multiple phases). Each of the sampled integrated signals at one or multiple phases can be represented as one equation of an equation set with unknowns. The unknowns can represent the time elapsed for the one or multiple returning light pulses and their parameters such as pulse widths, energy or reflectivity, or the like. By analyzing and solving the set of equations, these unknown parameters can be determined with reduced sensitivity to system noise and interference.

In accordance with some embodiments, A light detection and ranging (LiDAR) system comprises: a first light source configured to transmit one or more light pulses through a light emitting optics; a light receiving optics configured to receive one or more returned light pulses corresponding to the transmitted one or more light pulses, wherein the returned light pulses are reflected or scattered from an object in a field-of-view of the LiDAR system; a light detection device configured to convert at least a portion of the received one or more returned light pulses into an electrical signal; a signal processing device configured to process the converted electrical signal, wherein the processing includes amplifying, attenuating or modulating the converted electrical signal, wherein at least one of the signal processing device, light receiving optics and the light detection device is further configured to modulate one or more signals with respect to time in accordance with a modulation function; a signal integration device configured to integrate the processed electrical signal over a period of time during the light pulse emitting and receiving process to obtain an integrated signal; a signal sampling device configured to sample the integrated signal and convert the sampled signal to digital data; and an electronic computing and data processing unit electrically coupled to the first light source and a light detection device, the electronic computing and data processing unit is configured to determine a distance of a reflection or scattering point on the object in the field-of-view, wherein the said distance is determined based on a time difference between transmitting the one or more light pulses and detecting the returned one or more pulse signals, and wherein the time difference is determined by analyzing the sampled signal.

In accordance with some embodiments, a method for light detection and ranging (LiDAR) comprises: transmitting one or more light pulses through a light emitting optics; receiving one or more returned light pulse corresponding to the transmitted one or more light pulses, wherein the returned light pulses are reflected or scattered from an object in a field-of-view of the LiDAR system; converting at least a portion of the received one or more returned light pulses into an electrical signal, processing the electrical signal, wherein the processing includes amplifying, attenuating, or modulating the converted electrical signal along a signal chain, wherein at least one of the receiving, the converting, and the processing further comprises modulating one or more signals with respect to time in accordance with a modulation function; integrating the processed electrical signal over a period of time during the light pulse emitting and receiving process to obtain an integrated signal; sampling the integrated signal and convert the sampled signal to digital data; and determining a distance of a reflection or scattering point on the object in the field-of-view, wherein the said distance is determined based on a time difference between transmitting the one or more light pulses and detecting the one or more returned pulse signals, wherein the time difference is determined by analyzing the sampled signal.

### BRIEF DESCRIPTION OF THE DRAWINGS

For a better understanding of the various described aspects, reference should be made to the description below, in conjunction with the following figures in which like-referenced numerals refer to corresponding parts throughout the figures.

FIG. 1 illustrates an exemplary LiDAR system using pulse signal to measure distances to points in the outside environment.

FIG. 2 illustrates the exemplary LiDAR system using pulse signal to measure distances to points in the outside environment.

FIG. 3 illustrates the exemplary LiDAR system using pulse signal to measure distances to points in the outside environment.

FIG. 4 depicts a logical block diagram of the exemplary LiDAR system.

FIG. 5 depicts a light source of the exemplary LiDAR system.

FIG. 6 depicts a light detector of the exemplary LiDAR system.

FIG. 7 illustrates a conventional process for generating 3D imaging data in a LiDAR sensor.

FIG. 8 illustrates an exemplary flow chart for generating 3D imaging data using multi-stage multi-phase signal modulation, integration, sampling, and analysis techniques.

FIG. 9A illustrates an exemplary optical modulation configuration of a LiDAR system.

FIG. 9B illustrates another exemplary optical modulation configuration of a LiDAR system.

FIG. 10A illustrates an exemplary modulation function.

FIG. 10B illustrates an exemplary modulation function.

FIG. 10C illustrates an exemplary modulation function.

FIG. 10D illustrates an exemplary modulation function.

FIG. 10E illustrates an exemplary modulation function.

FIG. 10F illustrates an exemplary modulation function.

FIG. 11A illustrates an exemplary scenario of returning light pulse signals and the corresponding integrated signals.

FIG. 11B illustrates an exemplary scenario of returning light pulse signals and the corresponding integrated signals.

FIG. 11C illustrates an exemplary scenario of returning light pulse signals and the corresponding integrated signals.

FIG. 12 illustrates multiple sampling of the integrated signal within the integration period.

FIG. 13 illustrates an exemplary circuit and module implementation of the detection system with modulation options in different stages.

FIG. 14A illustrates an exemplary configuration for generating images of the illuminated strip of light in the field-of-view on the 1D detector array.

FIG. 14B illustrates an exemplary configuration for generating images of the illuminated strip of light in the field-of-view on the 1D detector array.

### DETAILED DESCRIPTION

### Overview

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples.

One type of LiDAR system uses time of flight of the light or some electromagnetic signals of other wavelengths to detect distances. For the purpose of this patent, the term “light” can represent ultraviolet (UV) light, visible light, infrared (IR) light, and/or an electromagnetic wave with other wavelengths. In a typical LiDAR system, a short (e.g., 2 to 5 nanoseconds) pulse of light is sent out and a portion of the reflected or scattered light is collected by a detector. By analyzing the time elapsed that the light pulse takes to travel and return to the detector (e.g., time of flight, or TOF), the distance of the object that scattered the light pulse can be determined.

In order to generate a high resolution three-dimension view of the objects in the field-of-view, a LiDAR system can for example, (a) raster one or more beams of light in both the horizontal and vertical directions; (b) scan a one-dimensional array, or a strip, of light sources and to collect the reflected or scattered light with a one-dimensional array or detectors; or (c) flood-flash a light pulse within the full or a portion of the field of the view and to collect the reflected or scattered light with a two-dimensional detector array.

Once the light pulse is emitted from the LiDAR light source, it propagates in the field-of-view and some portion of the light pulse may reach an object. At least a portion of the reflected or scattered light propagates backwards to the LiDAR system and is collected by an optical detector or one of the multiple optical detectors. By measuring the time elapsed between the transmitting and returning light pulse, one can determine the distance of the reflection or scattering point based on the speed of light. Direct measuring of TOF pulses requires high bandwidth on front-end analog signal circuits while keeping the noise floor low. This method also requires fast analog-to-digital conversion (ADC) that is typically at 1 GHz and requires cumbersome digital processing capability. Moreover, direct measuring of TOF may be associated with higher cost of components and excessive power consumption. Therefore, most LiDAR systems for cost-sensitive applications raster one or more beams of light in both, or at least one of, the horizontal and vertical directions with a beam steering mechanism and a small number of signal processing modules, or using a small number of 1D or 2D detector elements. These types of LiDAR systems may have limited resolution.

On the transmitting side, optical frequency chirping can also be used to determine TOF when it is combined with proper signal detection and processing techniques. But this method requires nimble and accurate optical frequency synthesis, high purity of frequency spectrum, and good linearity of frequency tuning. On the receiving side, because the optical frequency is about 4 orders of magnitude higher than today's 77 GHz radar and because optical light source has less spectrum purity, signal processing requires much higher bandwidth.

Three exemplary processes for generating high resolution 3D image information (e.g., point cloud) include: (a) a process of rastering one or more beams of light in both the horizontal and vertical directions, and detecting the returning signal with a single optical detector or a 1D or 2D detector array, (b) a process of scanning a 1D array in 1D or 2D direction and detecting the returning signal with a 1D or 2D detector array, and (c) a process of flashing the field-of-view, or a portion of the field-of-view, with a flood flash pulse and detecting the returning signal with a 2D detector array. In each of the embodiments described above, a critical process is to measure the time elapsed between the emission and return of the light pulse (time of flight, or TOF). Some embodiments of the present disclosure relate to methods and systems that determine the TOF using multi-stage multi-phase signal modulation, integration, sampling, and analysis technologies.

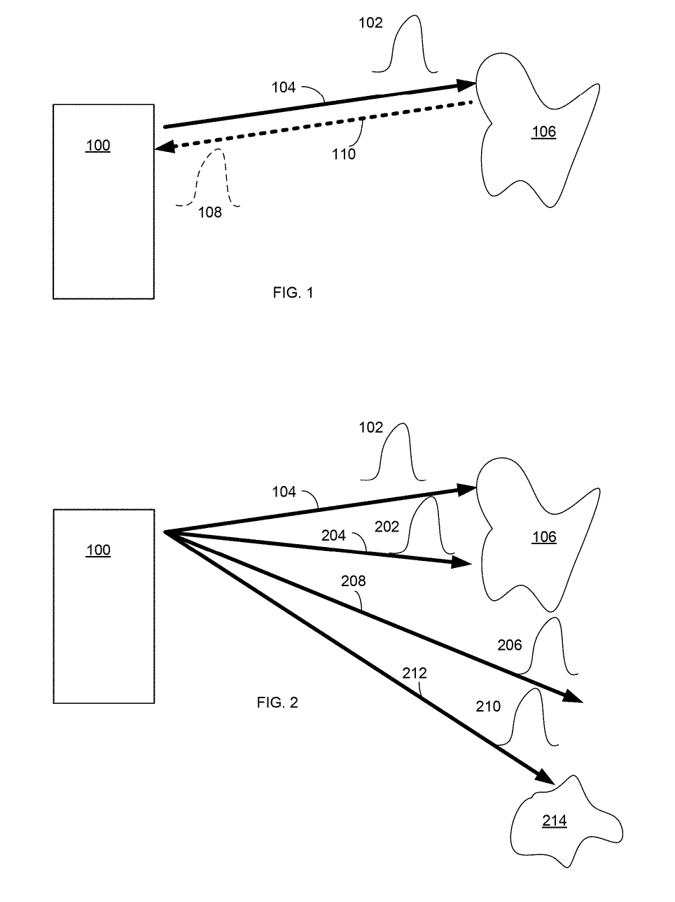

Some LiDAR systems use the time-of-flight of light signals (e.g., light pulses) to determine the distance to objects in the path of the light. For example, with respect to FIG. 1, an exemplary LiDAR system 100 includes a laser light source (e.g., a fiber laser), a steering system (e.g., a system of one or more moving mirrors), and a light detector (e.g., a photon detector with one or more optics). LiDAR system 100 transmits light pulse 102 along path 104 as determined by the steering system of LiDAR system 100. In the depicted example, light pulse 102, which is generated by the laser light source, is a short pulse of laser light. Further, the signal steering system of the LiDAR system 100 is a pulse signal steering system. However, it should be appreciated that LiDAR systems can operate by generating, transmitting, and detecting light signals that are not pulsed and/use derive ranges to object in the surrounding environment using techniques other than time-of-flight. For example, some LiDAR systems use frequency modulated continuous waves (i.e., “FMCW”). It should be further appreciated that any of the techniques described herein with respect to time-of-flight based systems that use pulses also may be applicable to LiDAR systems that do not use one or both of these techniques.

Referring back to FIG. 1 (a time-of-flight LiDAR system that uses light pulses) when light pulse 102 reaches object 106, light pulse 102 scatters and returned light pulse 108 will be reflected back to system 100 along path 110. The time from when transmitted light pulse 102 leaves LiDAR system 100 to when returned light pulse 108 arrives back at LiDAR system 100 can be measured (e.g., by a processor or other electronics within the LiDAR system). This time-of-flight combined with the knowledge of the speed of light can be used to determine the range/distance from LiDAR system 100 to the point on object 106 where light pulse 102 scattered.

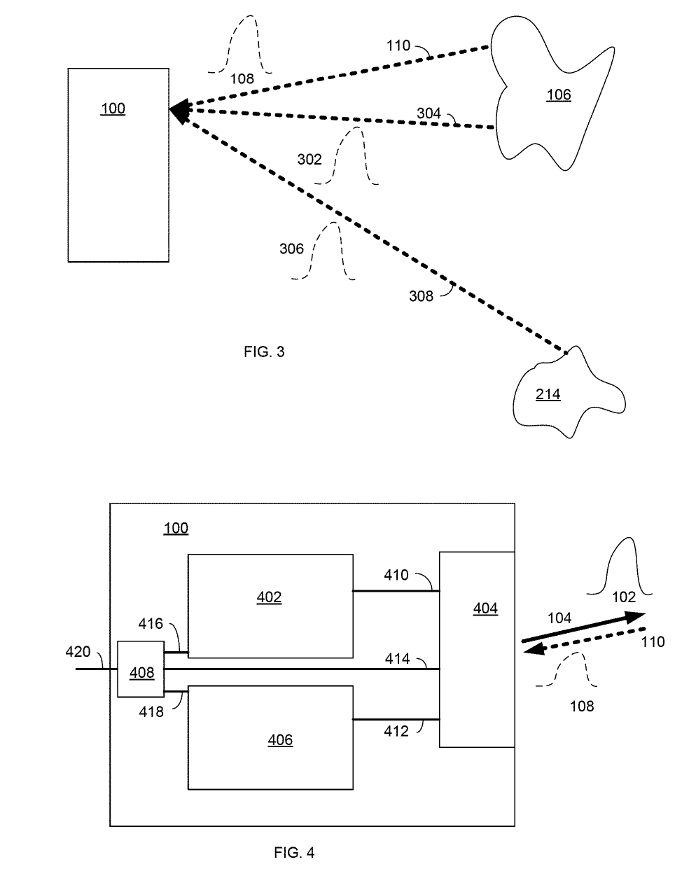

By directing many light pulses, as depicted in FIG. 2, LiDAR system 100 scans the external environment (e.g., by directing light pulses 102, 202, 206, 210 along paths 104, 204, 208, 212, respectively). As depicted in FIG. 3, LiDAR system 100 receives returned light pulses 108, 302, 306 (which correspond to transmitted light pulses 102, 202, 210, respectively) back after objects 106 and 214 scatter the transmitted light pulses and reflect pulses back along paths 110, 304, 308, respectively. Based on the direction of the transmitted light pulses (as determined by LiDAR system 100) as well as the calculated range from LiDAR system 100 to the points on objects that scatter the light pulses (e.g., the points on objects 106 and 214), the surroundings within the detection range (e.g., the field of view between path 104 and 212, inclusively) can be precisely plotted (e.g., a point cloud or image can be created).

If a corresponding light pulse is not received for a particular transmitted light pulse, then it can be determined that there are no objects within a certain range of LiDAR system 100 (e.g., the max scanning distance of LiDAR system 100). For example, in FIG. 2, light pulse 206 will not have a corresponding returned light pulse (as depicted in FIG. 3) because it did not produce a scattering event along its transmission path 208 within the predetermined detection range. LiDAR system 100 (or an external system communication with LiDAR system 100) can interpret this as no object being along path 208 within the detection range of LiDAR system 100.

In FIG. 2, transmitted light pulses 102, 202, 206, 210 can be transmitted in any order, serially, in parallel, or based on other timings with respect to each other. Additionally, while FIG. 2 depicts a 1-dimensional array of transmitted light pulses, LiDAR system 100 optionally also directs similar arrays of transmitted light pulses along other planes so that a 2-dimensional array of light pulses is transmitted. This 2-dimensional array can be transmitted point-by-point, line-by-line, all at once, or in some other manner. The point cloud or image from a 1-dimensional array (e.g., a single horizontal line) will produce 2-dimensional information (e.g., (1) the horizontal transmission direction and (2) the range to objects). The point cloud or image from a 2-dimensional array will have 3-dimensional information (e.g., (1) the horizontal transmission direction, (2) the vertical transmission direction, and (3) the range to objects).

The density of points in point cloud or image from a LiDAR system 100 is equal to the number of pulses divided by the field of view. Given that the field of view is fixed, to increase the density of points generated by one set of transmission-receiving optics, the LiDAR system should fire a pulse more frequently, in other words, a light source with a higher repetition rate is needed. However, by sending pulses more frequently the farthest distance that the LiDAR system can detect may be more limited. For example, if a returned signal from a far object is received after the system transmits the next pulse, the return signals may be detected in a different order than the order in which the corresponding signals are transmitted and get mixed up if the system cannot correctly correlate the returned signals with the transmitted signals. To illustrate, consider an exemplary LiDAR system that can transmit laser pulses with a repetition rate between 500 kHz and 1 MHz. Based on the time it takes for a pulse to return to the LiDAR system and to avoid mix-up of returned pulses from consecutive pulses in conventional LiDAR design, the farthest distance the LiDAR system can detect may be 300 meters and 150 meters for 500 kHz and 1 Mhz, respectively. The density of points of a LiDAR system with 500 kHz repetition rate is half of that with 1 MHz. Thus, this example demonstrates that, if the system cannot correctly correlate returned signals that arrive out of order, increasing the repetition rate from 500 kHz to 1 Mhz (and thus improving the density of points of the system) would significantly reduce the detection range of the system.

FIG. 4 depicts a logical block diagram of LiDAR system 100, which includes light source 402, signal steering system 404, pulse detector 406, and controller 408. These components are coupled together using communications paths 410, 412, 414, 416, and 418. These communications paths represent communication (bidirectional or unidirectional) among the various LiDAR system components but need not be physical components themselves. While the communications paths can be implemented by one or more electrical wires, busses, or optical fibers, the communication paths can also be wireless channels or open-air optical paths so that no physical communication medium is present. For example, in one exemplary LiDAR system, communication path 410 is one or more optical fibers, communication path 412 represents an optical path, and communication paths 414, 416, 418, and 420 are all one or more electrical wires that carry electrical signals. The communications paths can also include more than one of the above types of communication mediums (e.g., they can include an optical fiber and an optical path or one or more optical fibers and one or more electrical wires).

LiDAR system 100 can also include other components not depicted in FIG. 4, such as power buses, power supplies, LED indicators, switches, etc. Additionally, other connections among components may be present, such as a direct connection between light source 402 and light detector 406 so that light detector 406 can accurately measure the time from when light source 402 transmits a light pulse until light detector 406 detects a returned light pulse.

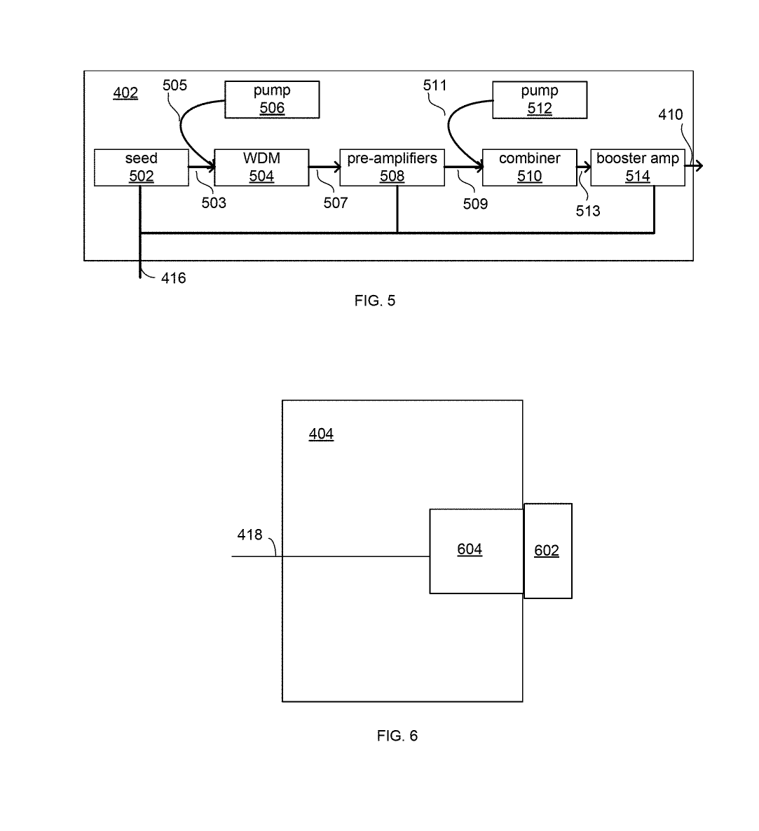

FIG. 5 depicts a logical block diagram of one example of light source 402 that is based on a laser fiber, although any number of light sources with varying architecture could be used as part of the LiDAR system. Light source 402 uses seed 502 to generate initial light pulses of one or more wavelengths (e.g., 1550 nm), which are provided to wavelength-division multiplexor (WDM) 504 via fiber 503. Pump 506 also provides laser power (of a different wavelength, such as 980 nm) to WDM 504 via fiber 505. The output of WDM 504 is provided to pre-amplifiers 508 (which includes one or more amplifiers) which provides its output to combiner 510 via fiber 509. Combiner 510 also takes laser power from pump 512 via fiber 511 and provides pulses via fiber 513 to booster amplifier 514, which produces output light pulses on fiber 410. The outputted light pulses are then fed to steering system 404. In some variations, light source 402 can produce pulses of different amplitudes based on the fiber gain profile of the fiber used in the source. Communication path 416 couples light source 402 to controller 408 (FIG. 4) so that components of light source 402 can be controlled by or otherwise communicate with controller 408. Alternatively, light source 402 may include its own controller. Instead of controller 408 communicating directly with components of light source 402, a dedicated light source controller communicates with controller 408 and controls and/or communicates with the components of light source 402. Light source 402 also includes other components not shown, such as one or more power connectors, power supplies, and/or power lines.

Some other light sources include one or more laser diodes, short-cavity fiber lasers, solid-state lasers, and/or tunable external cavity diode lasers, configured to generate one or more light signals at various wavelengths. In some examples, light sources use amplifiers (e.g., pre-amps or booster amps) include a doped optical fiber amplifier, a solid-state bulk amplifier, and/or a semiconductor optical amplifier, configured to receive and amplify light signals.

Returning to FIG. 4, signal steering system 404 includes any number of components for steering light signals generated by light source 402. In some examples, signal steering system 404 may include one or more optical redirection elements (e.g., mirrors or lens) that steer light pulses (e.g., by rotating, vibrating, or directing) along a transmit path to scan the external environment. For example, these optical redirection elements may include MEMS mirrors, rotating polyhedron mirrors, or stationary mirrors to steer the transmitted pulse signals to different directions. Signal steering system 404 optionally also includes other optical components, such as dispersion optics (e.g., diffuser lenses, prisms, or gratings) to further expand the coverage of the transmitted signal in order to increase the LiDAR system 100's transmission area (i.e., field of view). An example signal steering system is described in U.S. patent application Ser. No. 15/721,127 filed on Sep. 29, 2017, entitled “2D Scanning High Precision LiDAR Using Combination of Rotating Concave Mirror and Beam Steering Devices,” the content of which is incorporated by reference in its entirety herein for all purposes. In some examples, signal steering system 404 does not contain any active optical components (e.g., it does not contain any amplifiers). In some other examples, one or more of the components from light source 402, such as a booster amplifier, may be included in signal steering system 404. In some instances, signal steering system 404 can be considered a LiDAR head or LiDAR scanner.

Some implementations of signal steering systems include one or more optical redirection elements (e.g., mirrors or lens) that steers returned light signals (e.g., by rotating, vibrating, or directing) along a receive path to direct the returned light signals to the light detector. The optical redirection elements that direct light signals along the transmit and receive paths may be the same components (e.g., shared), separate components (e.g., dedicated), and/or a combination of shared and separate components. This means that in some cases the transmit and receive paths are different although they may partially overlap (or in some cases, substantially overlap).

FIG. 6 depicts a logical block diagram of one possible arrangement of components in light detector 404 of LiDAR system 100 (FIG. 4). Light detector 404 includes optics 604 (e.g., a system of one or more optical lenses) and detector 602 (e.g., a charge coupled device (CCD), a photodiode, an avalanche photodiode, a photomultiplier vacuum tube, an image sensor, etc.) that is connected to controller 408 (FIG. 4) via communication path 418. The optics 604 may include one or more photo lenses to receive, focus, and direct the returned signals. Light detector 404 can include filters to selectively pass light of certain wavelengths. Light detector 404 can also include a timing circuit that measures the time from when a pulse is transmitted to when a corresponding returned pulse is detected. This data can then be transmitted to controller 408 (FIG. 4) or to other devices via communication line 418. Light detector 404 can also receive information about when light source 402 transmitted a light pulse via communication line 418 or other communications lines that are not shown (e.g., an optical fiber from light source 402 that samples transmitted light pulses). Alternatively, light detector 404 can provide signals via communication line 418 that indicate when returned light pulses are detected. Other pulse data, such as power, pulse shape, and/or wavelength, can also be communicated.

Returning to FIG. 4, controller 408 contains components for the control of LiDAR system 100 and communication with external devices that use the system. For example, controller 408 optionally includes one or more processors, memories, communication interfaces, sensors, storage devices, clocks, ASICs, FPGAs, and/or other devices that control light source 402, signal steering system 404, and/or light detector 406. In some examples, controller 408 controls the power, rate, timing, and/or other properties of light signals generated by light source 402; controls the speed, transmit direction, and/or other parameters of light steering system 404; and/or controls the sensitivity and/or other parameters of light detector 406.

Controller 408 optionally is also configured to process data received from these components. In some examples, controller determines the time it takes from transmitting a light pulse until a corresponding returned light pulse is received; determines when a returned light pulse is not received for a transmitted light pulse; determines the transmitted direction (e.g., horizontal and/or vertical information) for a transmitted/returned light pulse; determines the estimated range in a particular direction; and/or determines any other type of data relevant to LiDAR system 100.

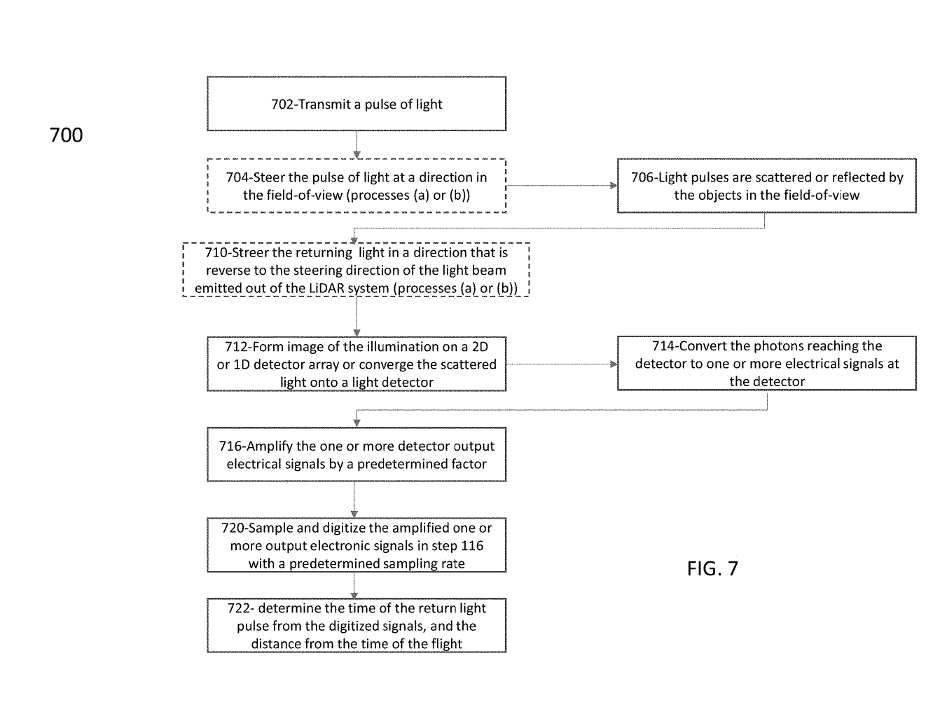

FIG. 7 illustrates a conventional process of generating 3D image in a LiDAR system. With reference to FIG. 7, in step 702, one or more short light pulses (e.g., light pulses with a 1 nanosecond to 5 nanoseconds pulse width or 30 nanoseconds or longer pulse width) are generated from a light source of the LiDAR system. Three exemplary processes for covering the field-of-view with the one or more pulses of light include: (a) a process of rastering one or more beams of light in both the horizontal and vertical directions; (b) a process of scanning a 1D array in 1D or 2D directions, and (c) a process of flashing the field-of-view, or a portion of the field-of-view, with a flood flash pulse. As shown in FIG. 7, in step 704, corresponding to the exemplary processes (a) and (b) as described above, a beam steering system steers or scans the one or more light pulses across the field-of-view. For the exemplary process (c), a beam steering system is not required. The beam steering system associated with the exemplary process (a) can include, for example, a system described in the U.S. Provisional Patent Application No. 62/441,280 (Attorney Docket No. 77802-30001.00) filed on Dec. 31, 2016, entitled “Coaxial Interlaced Raster Scanning System for LiDAR,” and the U.S. Non-provisional patent application Ser. No. 15/721,127 filed on Sep. 29, 2017, entitled “2D Scanning High Precision LiDAR Using Combination of Rotating Concave Mirror and Beam Steering Devices,” the content of which is hereby incorporated by reference in its entirety for all purposes. The beam steering system can also include a system described in the U.S. Provisional Patent Application No. 62/442,728 (Attorney Docket No. 77802-30005.00) filed on Jan. 5, 2017, entitled “MEMS Beam Steering and Fisheye Receiving Lens For LiDAR System,” and the U.S. Non-provisional patent application Ser. No. 15/857,566 filed on Dec. 28, 2017, entitled “MEMS Beam Steering and Fisheye Receiving Lens for LiDAR System,” the content of which is hereby incorporated by reference in its entirety for all purposes. One exemplary beam scanning system associated with the exemplary process (b) can include a system described in the U.S. Pat. No. 7,969,558 B2 granted on Jun. 28, 2011, entitled “High Definition LiDAR System,” the content of which is hereby incorporated by reference in its entirety for all purposes. One exemplary flashing LiDAR system associated with the exemplary process (c) can include a system described in the U.S. Pat. No. 5,157,451 granted on Oct. 20, 1992, entitled “Laser Imaging and Ranging System using Two Cameras,” the content of which is hereby incorporated by reference in its entirety for all purposes.

With reference to FIG. 7, in step 706, one or more light pulses, or a portion thereof, reach an object and are scattered or reflected in one or more directions. A portion of the scattered or reflected light pulses can travel backwards and reach a collection aperture of a detector of the LiDAR system. As shown in FIG. 7, in step 710, for processes (a) or (b), the one or more returning light pulses are steered in a direction that is reverse to the steering direction of the light pulses emitted out of the LiDAR system. In step 712, for process (a), the one or more returning light pulses are focused onto a light detector. For processes (b) and (c), the one or more returning light pulses form an image by an imaging optics on a 2D or 1D detector array. In step 714, the detector or each of the detector elements in the detector array converts the photons reaching the detector or detector element to one or more electrical signals. In some examples, a conversion parameter can be predetermined or preconfigured. In step 716, one or more output electrical signals generated in step 714 can be amplified using an amplification circuit or device by a predetermined factor. In step 720, the amplified one or more signals can be sampled and converted to a digital value at a predetermined sampling rate. In some embodiments, the digitized signal data can be collected within a time period of the expected maximum TOF corresponding to the farthest object in the field. In step 722, the digitized signal data can be analyzed to determine the TOF of one or more returning light pulses, and determine the distance from the LiDAR system to the reflection or scattering point of the objects.

In order to accurately measure the elapsed time between the emitting and the returning of the one or more light pulses, a sampling rate of 1 GHz or higher may be required to obtain centimeter-level accuracy for the distance to be measured. To preserve the fidelity of an echo signal, which may have a 2 ns rising/falling edge, an analog frontend having a bandwidth of about 170-180 MHz or higher may be desired. Moreover, in order to fully utilize, for example, a 1 GHz 8-bit ADC with a 1 Vp-p (1 volt peak-to-peak) input, an upper limit of the total noise floor before the ADC may be required to be less than 70 nV/rtHz. Thus, to accurately measure the elapsed time in a conventional LiDAR imaging process may require high-speed and low noise analog circuits and high-speed ADC. The cost of the high-speed and low-noise analog circuits and high-speed ADC can be increased or extraordinary (e.g., hundreds of dollars). Further, these circuits may consume excessive power (e.g., a few watts of power). Another disadvantage of the convention LiDAR imaging process includes requiring tight jitter specification for the sampling clock, in order to obtain high resolution. This requirement further increases the cost and power consumption of the LiDAR system. In addition, the complexity, the illumination power requirement and throughput increase from a single detector to a 2D array of detectors. For fixed illumination power (e.g., illumination power capped by the FDA eye safety requirement), achievable signal-to-noise ratio (SNR) decreases from a single point detector to a 2D array of detectors.

In some embodiments, the present disclosure describes methods and systems that determine the time of flight of one or more light pulses using multi-stage multi-phase signal modulation, integration, sampling, and analysis techniques.

### Method

Next, the methods and systems that can determine the time of flight of one or more light pulses using multi-stage multi-phase signal modulation, integration, sampling, and analysis techniques are described in detail.

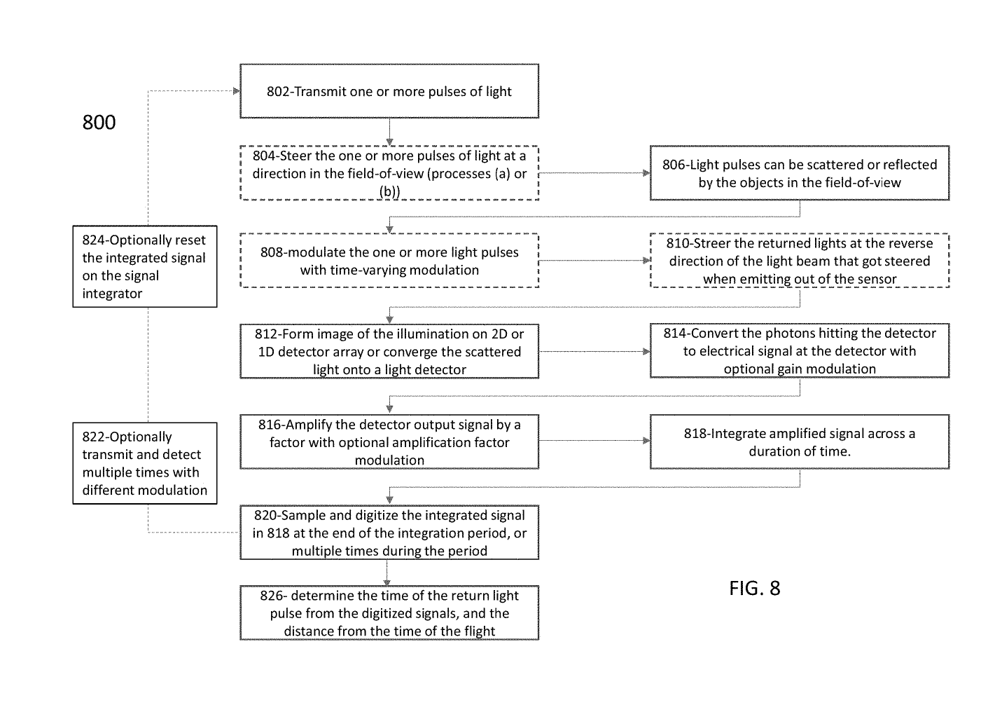

FIG. 8 illustrates an exemplary process 800 for generating 3D imaging data using multi-stage multi-phase signal modulation, integration, sampling, and analysis techniques. In step 802, a light source of a LiDAR system can transmit one or more pulses of light. In some embodiments, the light can be one or more of a laser light, an incandescent light, a fluorescent light, an LED light, and any other types of light. The light can have at least one of one or more wavelengths in the visible spectrum, one or more wavelengths in the infrared spectrum, one or more wavelengths in the terahertz range, or one or more wavelengths in the ultra violet spectrum. The pulse width of one or more light pulses can be, for example, 1-5 nanoseconds, 10 picoseconds to 1 nanosecond, or 5-200 nanoseconds.

In step 804, an optional beam steering apparatus of the LiDAR system can steer the one or more pulses of light at a direction in the field-of-view for a scanning process (e.g., processes (a) or (b) as described above). For a process where one or more pulses flood-illuminate the entire field-of-view (e.g., process (c) as described above) and where the one or more returning pulses are imaged onto a 2D detector array, the optional beam steering apparatus may not be required.

In step 806, at least a portion of the one or more light pulses emitted to the field-of-view may reach an object, and may be reflected or scattered in one or more directions. A portion of the reflected or scattered light can propagate in the reverse direction towards the LiDAR system, and can be collected by receiving optics of the LiDAR system.

In step 808, the collected returning lights can be optionally modulated by an optical modulator with, for example, time-varying modulation. In one embodiment, Pockels cells in combination with polarizers can be used as optical modulators as described in the article “Electro-Optic Devices in Review, The Linear Electro-Optic (Pockels) Effect Forms the Basis for a Family of Active Devices, by Robert Goldstein, Laser & Applications April 1986;” and in the article “Polarization Coupling of Light and Optoelectronics Devices Based on Periodically Poled Lithium Niobate, by Xianfeng Chen et al., Shanghai Jiao Tong University, China, Frontiers in Guided Wave Optics and Optoelectronics, February 2010).” The contents of both articles are hereby incorporated by reference in their entirety for all purposes. In some embodiments, crystals such as Ammonium Dihydrogen Phosphate (ADP), Potassium Dideuterium Phosphate (KDP), Lithium Niobate (LN) and Deuterated Potassium Dihydrogen Phosphate (DKDP), or the like, or Periodically Poled Lithium Niobate (PPLN) can be used as Pockels cells.

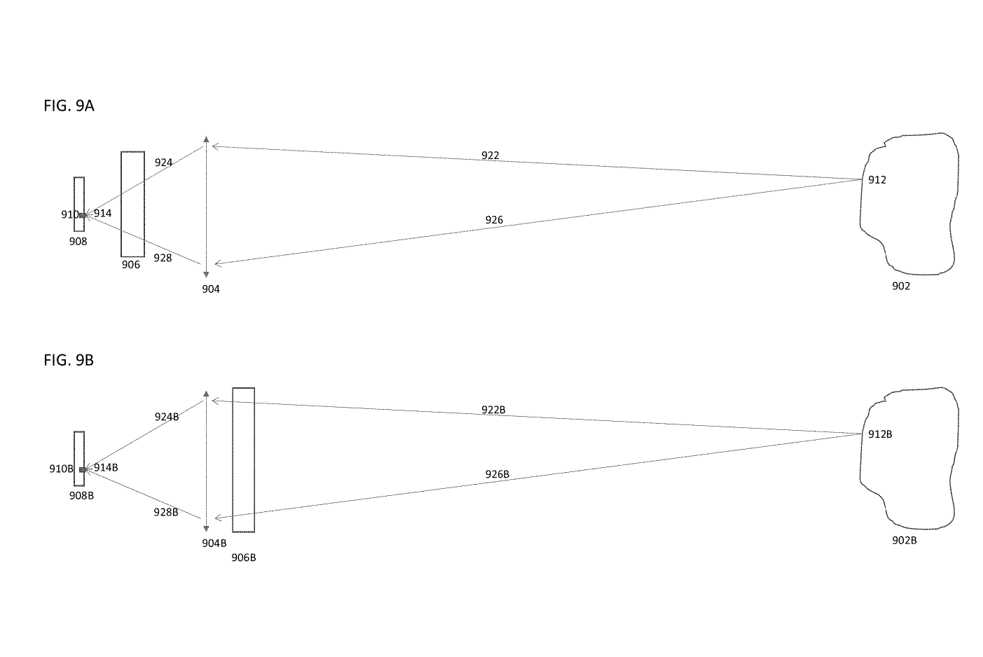

In some embodiments, for exemplary processes (b) or (c), to determine the distance of an object or a portion of an object (e.g., a point of the object) in the field-of-view from the LiDAR system, an optical system can be used to form an image of the object on a 1D or 2D detector array. One embodiment is shown in FIG. 9A. With reference to FIG. 9A, a portion 912 of an object 902 (e.g., a point of object 902) may be illuminated by one or more light pulses (not shown in FIG. 9A). At least a portion of one or more scattered or reflected light pulses can propagate backward through one or more collection light paths, for example, light paths 922 and 926. The one or more scattered or reflected light pulses can be collected by an objective lens 904, which can focus the light pulses (through light paths 924 and 928) to a point 914 on the pixel 910 of a detector 908. As shown in FIG. 9A, in one embodiment, an optical modulator 906 is disposed between the objective lens 904 and the detector 908. Correspondingly, with reference to FIG. 8, the optical modulation step 808 can be included in the imaging step 812 (which, with reference to FIG. 9A, includes the use of the objective lens 904 and the detector 908), instead of being disposed between step 806 and step 810. An embodiment similar to that illustrated in FIG. 9A is described in the U.S. Patent Application No. US 2010/0128109 A1. In this embodiment, the optical modulator 906 may be required to have substantially uniform modulation characteristics across all the directions of the light coming out of the objective lens 904. This is because, for example, light pulses traveling along light paths 924 and 928 can have vastly different approaching angles, but are both from the same portion 912 (e.g., a point) of object 902. Therefore, they need to be focused to the same point 914 after going through the optical modulator 906. However, typical Pockels cells are capable of generate substantially uniform modulation for incident light beams deviating by a very small angle such as less than 1 degree. For light beams propagating along light paths 924 and 928 and in other directions, Pockels cells may experience substantially different amount of modulation going through the optical modulator 906, thus resulting in undesired quality of image at point 914.

With reference to FIG. 9B, in some embodiments, an optical modulator 906B can be disposed in front of an objective lens 904B. Correspondingly, with reference to FIG. 8, the optical modulation step 808 can be disposed before the imaging step 812 and after the light scattering or reflection step 806, but can be either before or after the optional beam steering step 810. Referring back to FIG. 9B, for scattered or reflected light from objects that is located beyond a threshold distance (e.g., farther than 1.5 meters) from the LiDAR system, the range of angles (e.g., the angle between light paths 922B and 926B) expanding across the collection optics 904 can be small. For example, for an aperture size of 25 mm, at 1.5 meters, the angle is about 1 degree, and this angle can be significantly smaller for distance much farther than 1.5 meters. As a result, all the light pulses coming from the same scattering point 912B can have substantially the same amount of modulation going through the optical modulator 906B before entering the imaging optics 904B, thus resulting in improved image quality at point 914B.

With reference to FIG. 8A, at the optional step 810, the received light signals can be steered in a similar manner but in a direction that is reverse to the steering direction of the light beam emitted out of the LiDAR system. Steering the received light signals at the reserve direction enables returning light signals to be received at an optical detector relatively stationary with respect to the light source. In one embodiment, a beam steering apparatus associated with step 810 can physically be the same apparatus as the beam steering apparatus associated with step 804 (e.g., the beam steering apparatus for the emitting light beam). In another embodiment, the beam steering apparatus associated with step 810 can physically be a different apparatus from the beam steering apparatus associated with step 804, but can be configured to steer the light pulses in a substantially synchronous manner as the steering in step 804, so that the returning light signal can be received by the detector. In another embodiment, the beam steering apparatus associated with step 810 can include wide angle receiving optics that can direct light collected from a wide angle to a small focused point as described in the U.S. Provisional Patent Application No. 62/442,728 (Attorney Docket No. 77802-30005.00) filed on Jan. 5, 2017, entitled “MEMS Beam Steering and Fisheye Receiving Lens for LiDAR System,” and the U.S. Non-provisional patent application Ser. No. 15/857,566 filed on Dec. 28, 2017, entitled “MEMS Beam Steering and Fisheye Receiving Lens for LiDAR System,” the content of which is hereby incorporated by reference in its entirety for all purposes.

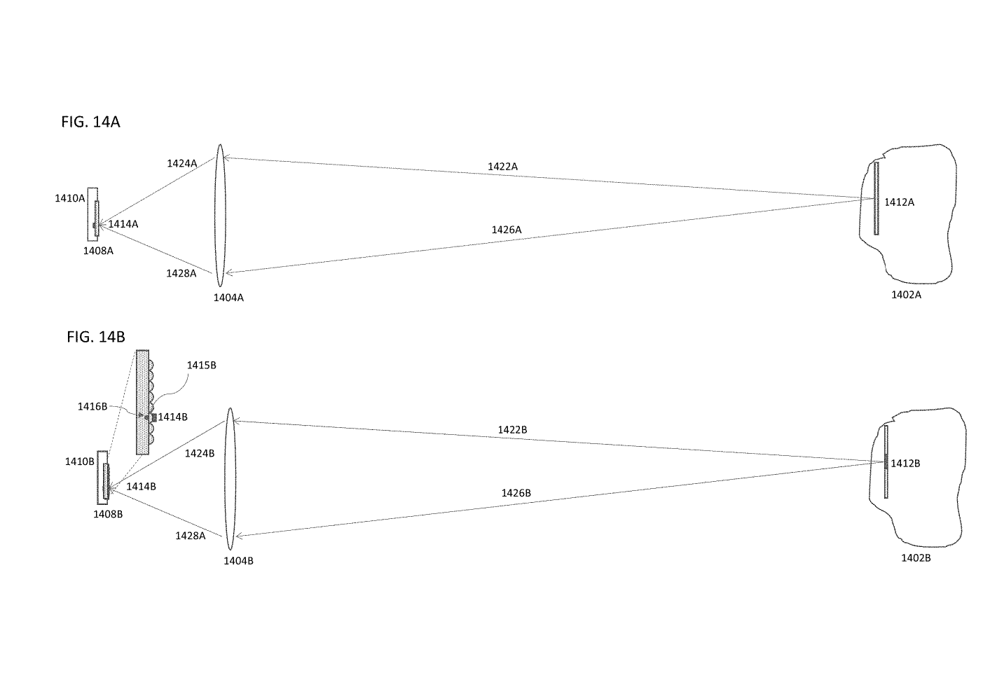

With reference to FIG. 8, at step 812, for process (a), the returning light can be focused to a small spot where a light detector is disposed. For process (b), the returning light can be focused in one direction to a width that can substantially fit the width of the active area of the 1D detector array. In the other direction, the returning light can either be imaged by an imaging optics (e.g., optics 1404B) to the entire length of the 1D detector array 1408B as shown in FIG. 14A or be further imaged by an array of micro imaging optics 1415B along the said other direction with substantially the same pitch as the detector array 1408B, so that the returning light can be focused or imaged to multiple collection elements along the detector array 1408B. As shown in FIG. 14B, for the light scattering at a bar section 1412B of the object 1402B, the returning light can form an image in front of the micro imaging optics 1415B (e.g., micro-lens), and can further be focused to a spot 1416B (e.g., a very small spot) on a detector element of detector array 1408B. In the embodiment illustrated in FIG. 14B, the active area along the vertical direction of the detector array 1408B can have a lower active area ratio, which can reduce the burden and cost to design and manufacture. In some embodiments, for process (c), the returning light from the field-of-view can be imaged on a 2D detector array. Similar to process (b), a 2D micro imaging optics (e.g., micro-lens) array with substantially the same pitch as the 2D detector array in both horizontal and vertical direction can be optionally disposed in front of the detector array to reduce the requirement of its active area ratio.

With reference back to FIG. 8A, at step 814, photons collected by each of the detector element of a detector or detector array can be converted into one or more electrical signals with optional gain modulation. The detector element can include, for example, one or more of a CMOS optical sensor, an Avalanche Photo Diode (APD), a PIN diode, or other devices that can convert optical signals to electrical signals. In one embodiment, a CMOS sensor can represent a plurality of electron wells, which collect free electrons associated with optical excitation. A CMOS sensor may not have any internal gain, but can be an integrator in nature.

In another embodiment, APD can be used as each of the optical detecting element. APDs can be thought of as special photo diode that provide a built-in first stage of gain through avalanche multiplication. By applying a high reverse bias voltage (typically 100-200 V in silicon), APDs show an internal current gain effect (multiplication factor M around 100) due to avalanche effect. In general, the higher the reverse voltage, the higher the gain. The gain of the APD can be optionally modulated within the time of flight of the light pulse for the designed maximum detection distance within the field-of-view.

With reference still to FIG. 8A, at step 816, the electrical signals generated by the light detector in step 814 can be further amplified. The amplification factor can be optionally modulated within the time of flight of the light pulse for a predetermined (e.g., design specified) maximum detection distance within the field-of-view.

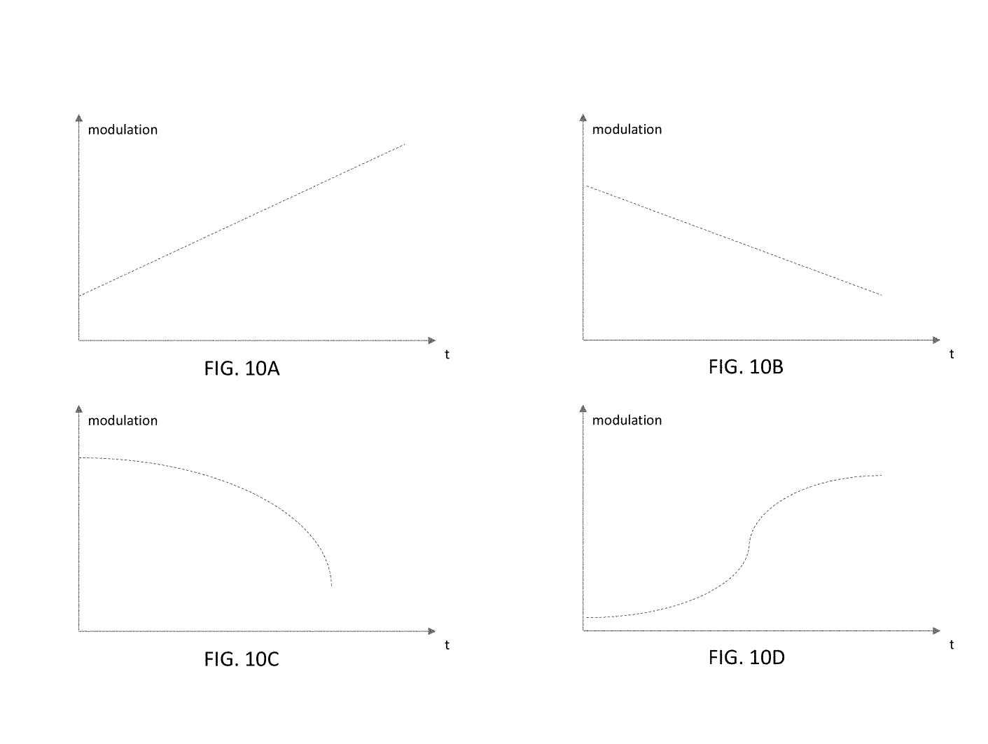

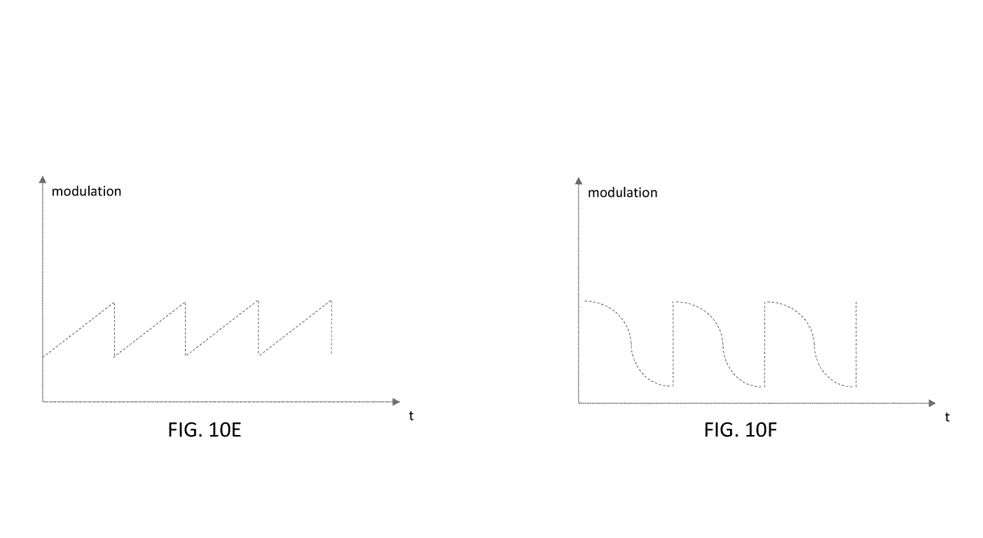

The signal modulations can be performed at any one or more of the steps 808, 814, and 816, or a combination thereof. For example, signal modulation can be performed with respect to optical signals and/or with respect to electrical signals generated based on the optical signals. In some embodiments, the modulation function with respect to time can change linearly with time as shown in FIG. 10A and FIG. 10B, change monotonically with non-linear functions as shown in FIG. 10C and FIG. 10D as examples, or can be piecewise monotonic and non-linear as shown in FIGS. 10E and 10F as examples.

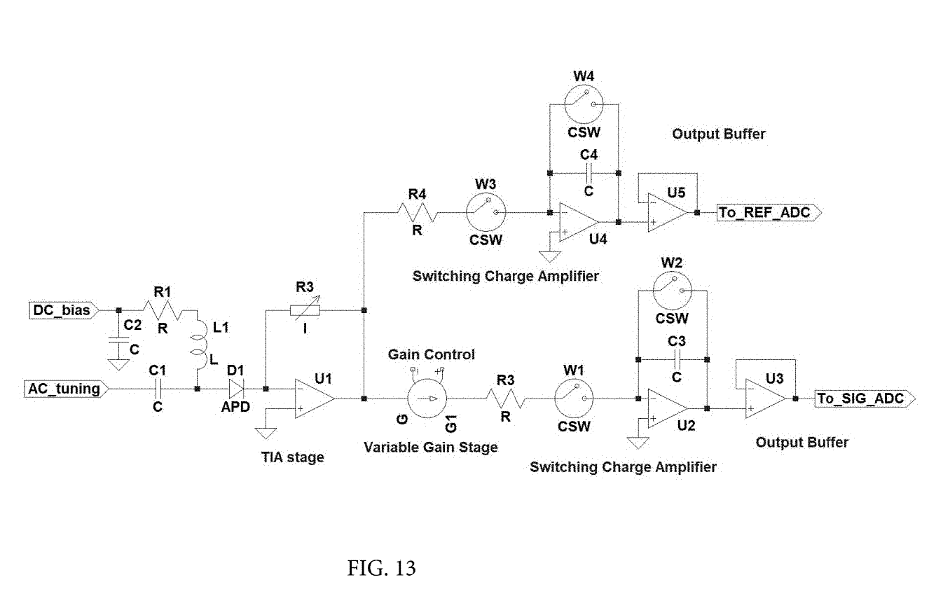

With reference back to FIG. 8, at step 818, the amplified signal generated at step 816 can be integrated with respect to time for a duration of time. The duration of time of the integration can be one or more times, or a fraction of, the maximum time of flight of the light pulse returning to the LiDAR system after reaching an object in the field-of-view. For example, if a predetermined (e.g., design specified) maximum distance of the LiDAR system is 150 meters, then the maximum time of flight is about 1 microsecond. So the duration time of the integration can be one or a few microseconds, a few nanoseconds, a few dozen nanoseconds, or a few hundred nanoseconds. An exemplary implementation of a signal integrator (e.g., a switching charge amplifier) is illustrated in FIG. 13.

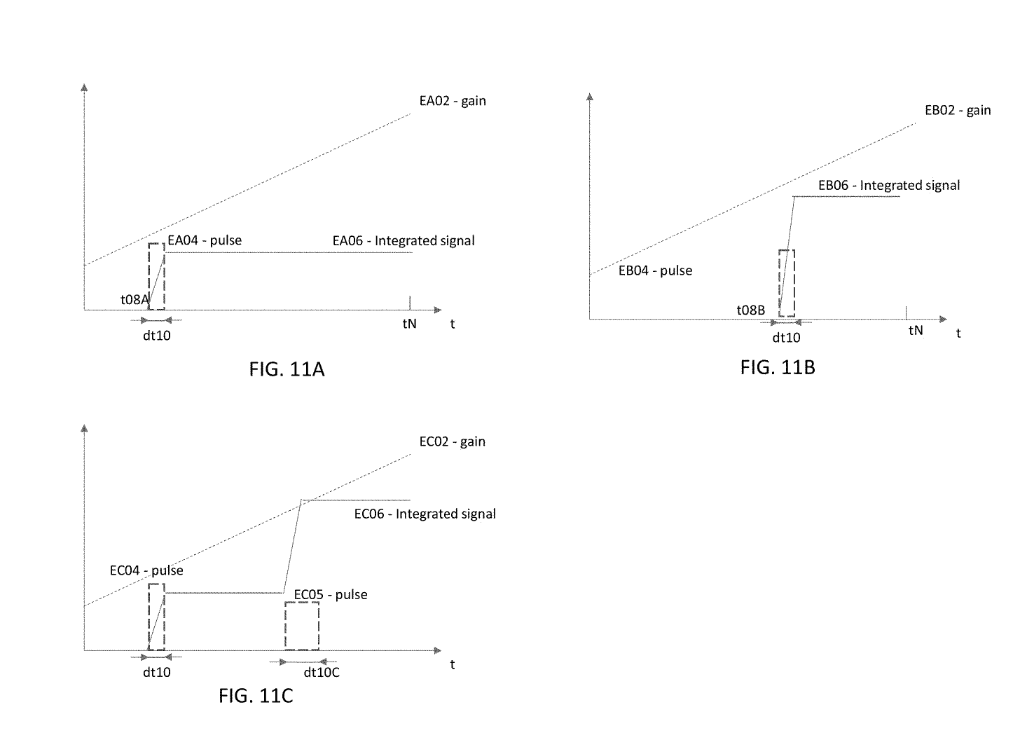

FIGS. 11A-11C illustrate three exemplary scenarios of returning light pulse signals and their corresponding integrated signals. In FIGS. 11A-11C, the horizontal axis represents time t, and the vertical axis represents magnitude of the signals or the gain modulations. As shown in FIG. 11A, in some embodiments, the signal modulations performed at one or more steps 808, 814, and 816 can be combined and can have an effective gain modulation curve EA02. FIG. 11A also illustrates that a returning light pulse EA04 reaches a detector at time t08A with a pulse width dt10. In one example, the gain modulation curve EA02 can vary (e.g., linearly) over time t. Thus, the integrated signal with respective to time can be represented by curve EA06, which can be represented mathematically as S=∫₀^{t}^{_{N}} u(t)·g(t) dt, where u(t) is the instantaneous signal without the modulated gain and g(t) is the gain modulation curve EA02.

As shown in FIG. 11B, in some embodiments, a returning light pulse can reach the detector at a later time t08B, and can have the same pulse width dtl0, the same magnitude, and a gain modulation curve EB02 (e.g., the same as EA02). The integrated signal can be represented as curve EB06, where the integrated signal magnitude at the end of the integration time tN is different from the magnitude illustrated in FIG. 11A. In another scenario as shown in FIG. 11C, the emitted light pulse may generate two returning lights pulses EC04 and EC05. In some examples, the two returning light repulses can be from the reflected or scattered light, which can be generated from different portions of a light beam reaching objects at different distances in the field-of-view. In some examples, the first returning light pulse can be from a partial reflection from a surface (e.g., a glass) and the second returning pulse can be from another object farther away behind the surface (e.g., the glass). The widths of the two returning light pulses EC04 and EC05 can also be different, as shown in FIG. 11C, for example, the width dtl0 of the pulse EC04 is different from the width dt10C of the pulse EC05. The integrated signal of the two returning pulses EC04 and EC05 can be represented by curve EC06, which may have two steps connected with two different slopes.

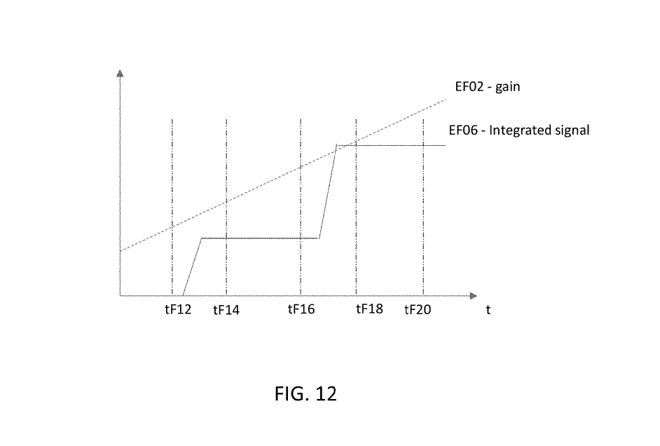

With reference back to FIG. 8, at step 820, the integrated signal can be sampled one or more times during the duration time of the integration, and the sampled signal can be further digitized with an analog to digital converter. As shown in FIG. 12, at each sampling time, for example, at time tF12, or time tF14, or time tF16, or time tF18, or time tF20, the instantaneous signal is sampled in a short period of time (e.g., one or a few nanoseconds, or a fraction of one nanosecond) and then is further digitized with desired analog to digital resolution. For the example illustrated in FIG. 12, the five integrated signals sampled at time instances tF12, tF14, tF16, tF18, and tF20 are digitized with a predefined accuracy and stored for further processing.

Continue referring to FIG. 8, the steps 802 through 820 described above can be optionally repeated multiple times within a short period of time, with pulse emitted at each repetition separated from that in the next repetition by the maximum time of flight of the detection distance, and may optionally add a short duration of time as margin, as shown in step 822. In each of the repetition, the modulation signal in any one or more of the steps 808, 814, and 816 can be different from those in other repetitions. Optionally in between two consecutive pulses, the integrated signal can be reset on the signal integrator to avoid signal saturation. Alternatively a circuit associated with the signal integrator can include a comparator circuit, so that when the integrated signal reaches a pre-designed threshold, a reset switch can be triggered automatically to reset the signal integrator.

One challenge for a LiDAR system is how to handle the signals collected with very wide dynamic range. Because of the different reflection or scattering efficiency and different distances from the LiDAR system, at some locations the returning signals may be very strong, while at other locations the returning signals may be very weak. In some embodiments, after one light pulse is emitted and the returning light pulse is collected, integrated, digitized, analyzed and used to determine the distance of a reflection or scattering position, or multiple reflection or scattering positions, from the LiDAR system, the system can determine whether the strength of the returning signal is within a predefined dynamic detection range, is too strong that it causes saturation, or too weak that the signal is dominated by random noise. In some embodiments, when the signal is either saturated or too weak, the data in regions at neighboring scanning angles can be utilized to provide additional information that can help identify and confirm the situation of saturation or insufficient signal. Many methods such as clustering or segmentation algorithms can be used to group the scattering or reflection location with other neighboring data points that belong to the same object. If the signal from the said location is saturated, the power of the next pulse can be adjusted to a lower level and/or the gain of the signal detection and processing modules can be adjusted to a lower level, such that the strength of the returning signal falls within the desired dynamic detection range. If the signal from the said location is too weak, the power of the next pulse can be adjusted to a higher level and/or the gain of the signal detection and processing modules can be adjusted to a higher level, such that the strength of the returning signal falls within the desired dynamic detection range. The said adjustment described above can be done iteratively and multiple times for succeeding pulses, so that many or all scattering or reflection locations in the field-of-view can have returning signals within the desired dynamic detection range.

With reference to FIG. 8, in step 826, after all the pulses and returning signals are integrated and digitally sampled, the times of the returning pulses can be determined; and the distance of the scattering or reflecting spot from the LiDAR system can be determined based on the speed of light.

In some embodiments, for a process 800, M repetitions of light pulse emission and collection in steps 802 through 820 can be completed. And each of the Ni sampled digitized integrated signals at the i_th light pulse emission can be represented by S(i, 1), S(i, 2), . . . , S(i, Nᵢ). For the signal S(i,j) that is sampled at time t(i,j), it can be calculated as

S(i,j)=∫₀^{t(i,j)}u(t)·g(t)dt (1),

where u(t) represents the instantaneous signal without the modulated gain effect, and g(t) is the time-varying modulation of the gain. In one embodiment as shown in FIG. 10A or FIG. 10B, where the gain function g(t) can be represented by g(t)=a+bt, for a pulse Pₖ with a rectangular pulse shape of height hₖ and width dₖ that reaches the detection element at time tₖ, its contribution to the integrated signal Sₖ can be represented by Sₖ=Eₖ(a+btₖ+½bdₖ), where Eₖ=hₖ·dₖ representing the total amount of the light pulse energy reaching the LiDAR system. In this embodiment, the integrated signal in equation (1) can then be written as S(i,j)=Σₖ₌₁^{K}^{ⱼ} Eₖ(aᵢ+bᵢtₖ+½bᵢdₖ), where Kⱼ represents the number of pulses reaching the LiDAR system up to time t(i,j).

If the width of the light pulse dₖ is much smaller than the time tₖ, and it can be determined that there is only one returning pulse before time t(i,j), and the equation for S(i,j) can be simplified to

S(i,j)=E₁(aᵢ+bᵢt₁) (2)

where the only unknown variables in equation (2) are E₁ and t₁. In some embodiments, with one or more iterations of light pulse emission and collection with different sets of the modulation coefficients (aᵢ, bᵢ) within a short period of time (e.g., within 2 microseconds, 5 microseconds, 10 microseconds, or 100 microseconds), during which the objects and the LiDAR sensors are substantially stationary, the values of E₁ and t₁ can be determined from a plurality of equations. When there are three or more equations in this equation set with two unknown variables E₁ and ti, the solution becomes an optimization problem and the optimized solution can be less sensitive to the random noise in the system. Another benefit of solving two unknowns with more than two equations is for detecting and filtering out outliers, which can be generated from signals coming out of another LiDAR system, from other interference source in the environment, or from noise within the system itself. This can be illustrated by the following example. Rewrite equation (2) to

S(i,j)=E₁aᵢ+F₁bᵢ (3)

where F₁=E₁t₁. In equation (3), each data sample (S(i,j), aᵢ, bᵢ) can be represented by a point in the three dimensional space with each of the three axes representing S, a, and b. In some examples, the points representing all the pulses can be on the same 2D plane because they all share the same values of E₁ and F₁, where the two unknowns Eₗ and Fᵢ represent the directional vector of the plane. If there is interference from other LiDAR systems, from other interference sources, or from a large noise within the system itself, the corresponding data sample can behave like an outlier point outside the 2D plane described above. Many outlier detection techniques can be used for detecting and filtering out such outlier(s) and calculate the fitted coefficient values accordingly. Some exemplary methods are described in the paper titled “Some Methods of Detection of Outliers in Linear Regression Model-Ranjit”, which is hereby incorporated by reference. A skilled artisan can appreciated that other techniques can be used for outlier detection and removal.

In some embodiments, a skilled artisan can appreciate that when the pulse widths are sufficiently wide and/or the modulation is in a more complicated format instead of a linear function with respect to time, these parameters can be included in the integration equation (1) in the equation set, and the unknown parameters can be determined in similar methods as described before.

Comparing to the high-speed signal sampling technique described in the background section where gigahertz analog to digital converter is required to achieve accurate returning pulse time measurement, the method described here requires significant lower operational speed (e.g., megahertz or 10 megahertz) for the analog to digital converter. In addition, lower operational speech ADC can be, for example, 10 times or even 100 times less expensive. Even with the signal integration circuit (one embodiment is shown in FIG. 13), the total amount of cost savings can still be significant.

### System

In this section, some embodiments of system implementation are described.

In some embodiments, as described above, signal modulation can be performed across one or more of the three stages in the receiving path (e.g., steps 808, 814, and 816). Signal modulations can be performed with respect to optical signals and/or electrical signals. In some examples, an optical stage can include an optical modulator. For example, Pockels Cell can be included in an optical stage to obtain temporal variable gain. In a detection stage, some types of detectors such as APD (Avalanche Photo Diode), PMT (Photo Multiplier Tube), and/or MCP (Micro Channel Plate) can to configured to obtain temporal variable gain by tuning the bias voltage. In an electrical signal processing stage, an electrical modulator can be used. For example, a VGA (variable gain amplifier) can be used to provide temporal variable gain by tuning the control voltage.

In some embodiments, an optical modulation may utilize an optical amplitude modulator. For 2D array imaging, a high-speed tuning, a high voltage driver for the modulator, and large clear aperture and numerical aperture can be required.

A 1D imaging array can have advantages in modulator construction because of its astigmatic nature. For example, one can use a slab of crystal and the receiving optical path can use cylindrical optics. The PPLN crystal has similar geometry. It can reduce driving voltage requirements and reduce manufacturing complexity because no layered structure as optical slicer does.

In the illustration of an exemplary imaging optical path in FIG. 9B, different pixels in imaging plane can correspond to different propagation directions, and light paths that come from the same scattering or reflection point can enter the optical modulator 906B at a substantially the same incident angle. Light travels along the same direction can thus experience the same optical modulations. In this manner, high image quality can be achieved.

Exemplary methods for realizing detection modulation are described. In some examples, an APD modulation can be realized by combining a low frequency DC bias (e.g., 100-200V) and a high frequency AC bias, as indicated in FIG. 13. The AC bias can have a sawtooth, exponential, monotone, and/or arbitrary waveform. In some examples, a PMT modulation can be realized with a similar AC/DC combiner applied onto the first stage of a PMT.

In some embodiments, a reference signal generated and processed. For example, in an optical stage using an optical beam splitter, a reference signal can be propagated without modulation while the actual signal can go through an optical modulation. In some embodiments, a beam splitter can also be implemented in an optical detection method. For example a reference signal can be used for a fixed gain detection while an actual signal can be used for a modulated gain detection. In some embodiments, for electrical gain control, the trans-impedance amplifier can feed the reference arm and signal arm simultaneously. The reference arm can include a fixed gain stage while the signal arm can include a variable gain stage.

In some embodiments, signal modulation can be performed using amplifier modulation. In electrical signal chain, for example, a VGA (variable gain amplifier) can also provide temporal variable gain by tuning control voltage.

In some embodiments, a signal integrator can convert current pulses into voltage level and can reduce the bandwidth requirement on the following signal path. For example, a fast charge amplifier (e.g., an amplifier used in nuclear electronics) can be used as electrical integrator for such purpose. Integrated circuit such as IVC102 from Texas Instrument can also serve the same purpose.

Since one can achieve amplitude modulation in three stages of the receiving path, either optically or electrically, hybrid method of combining multiple stages' modulations can increase the system dynamic range and provide flexibility in system partition. For example, 90 dB variable gain can be distributed as 20 dB in optical domain, 20 dB in optical detection and 50 dB in electrical amplification stage. A skilled artisan can appreciate that other distribution schemes can also be configured.

In some embodiments, multiple scan can be performed. For example, during the multiple scan, each scan can have different time windows of modulation for different distance detection range. As another example, each scan can have different pulse intensity for higher dynamic range.

It is appreciated that multiple modulations, more complicated modulation techniques, and/or multiple sampling can be performed to, for example, solve multiple-return scenario, reduce interference issue, and increase dynamic range.

In some embodiments, the LiDAR system can include a transmitter section and a receiver section. Two parameters associated with a transmitter (e.g., pulse width and energy per pulse) can be configured or controlled to obtain improved performance. In some examples, a receiver section can include an optical setup (e.g., optical lens), an optical receiver (optical to electrical conversion), and electrical signal processing components. In some examples, an optical setup can include an optical modulator (e.g. Pockels Cell) that can provide temporal variable gain.

In some embodiments, the LiDAR system can include an optical detector gain modulator, an optical receiver, such as APD (Avalanche Photo Diode), PMT (Photo Multiple Tube) or MCP (Micro Channel Plate). In some examples, the optical receiver can also provide temporal variable gain by timely tuning bias voltage.

FIG. 13 illustrates an exemplary circuit and module implementation of the detection system with modulation options in different stages. With reference to FIG. 13, the far left portion includes a bias circuitry for APD. The DC_bias terminal can provide a base voltage and the AC_tuning terminal can enable fast tuning to provide temporal gain. When one or more photons reach the APD, electrical current proportionate to the adjustable gain (which can be modulated with respect to time) can be generated and feeds into the TIA stage, which converts photo current into electrical voltage. The conversion coefficient relates to the variable resistor R3, which can also be designed to be modulated with time-varying signal. The output of TIA stage can drive a signal arm and a reference arm substantially simultaneously. The signal arm can include a VGA (variable gain amplifier) to provide temporal gain in electrical manner. Both arms can have an integrator to convert pulses into voltage level for further ADC processing. A switching charge amplifier, which follows the VGA stage, can convert one or more current pulses into voltage levels. In this manner, it reduces the requirements on bandwidth and digital processing power. As a result, a reduced speed ADC (1˜10 MHz speed) can be used. This signal processing configuration can be used to implement large scale parallel processing, which can be used to significantly increase LIDAR points cloud throughput (image rendering throughput).

Various exemplary embodiments are described herein. Reference is made to these examples in a non-limiting sense. They are provided to illustrate more broadly applicable aspects of the disclosed technology. Various changes may be made and equivalents may be substituted without departing from the true spirit and scope of the various embodiments. In addition, many modifications may be made to adapt a particular situation, material, composition of matter, process, process act(s) or step(s) to the objective(s), spirit or scope of the various embodiments. Further, as will be appreciated by those with skill in the art, each of the individual variations described and illustrated herein has discrete components and features which may be readily separated from or combined with the features of any of the other several embodiments without departing from the scope or spirit of the various embodiments.

Exemplary methods, non-transitory computer-readable storage media, systems, and electronic devices are set out in the following items:
1. A light detection and ranging (LiDAR) system, comprising:
   a first light source configured to transmit one or more light pulses through a light emitting optics;
   a light receiving optics configured to receive one or more returned light pulses corresponding to the transmitted one or more light pulses, wherein the returned light pulses are reflected or scattered from an object in a field-of-view of the LiDAR system;
   a light detection device configured to convert at least a portion of the received one or more returned light pulses into an electrical signal;
   a signal processing device configured to process the converted electrical signal, wherein the processing includes amplifying, attenuating or modulating the converted electrical signal,
      wherein at least one of the signal processing device, light receiving optics and the light detection device is further configured to modulate one or more signals with respect to time in accordance with a modulation function;
   a signal integration device configured to integrate the processed electrical signal over a period of time during the light pulse emitting and receiving process to obtain an integrated signal;
   a signal sampling device configured to sample the integrated signal and convert the sampled signal to digital data; and
   an electronic computing and data processing unit electrically coupled to the first light source and a light detection device, the electronic computing and data processing unit is configured to determine a distance of a reflection or scattering point on the object in the field-of-view, wherein the said distance is determined based on a time difference between transmitting the one or more light pulses and detecting the returned one or more pulse signals, and wherein the time difference is determined by analyzing the sampled signal.
2. The system of item 1, wherein the one or more light pulses have one or more pulse widths of less than 1 nanosecond, 1 to 5 nanoseconds, or 5 to 200 nanoseconds.
3. The system of any of items 1-2, wherein the light emitting optics comprises a beam steering system that steers an emitting light in one or two directions.
4. The system of any of items 1-3, wherein the light emitting optics diverge a light coming out of the light source to an angle of 1 to 270 degrees in the field-of-view.
5. The system of any of items 1-4, wherein the light receiving optics includes an optical modulation device that modulates the intensity or polarization state or phase of any one or combination of two or more of the said properties of the light passing through it with respect to time.
6. The system of item 3, wherein the light receiving optics includes the beam steering system.
7. The system of item 3, wherein the light receiving optics includes a second beam steering system that is physically different from the beam steering system, and the second beam steering system steers the received light beam in a substantially synchronous manner in the reverse direction as the beam steering system.
8. The system of any of items 1-7, wherein the light receiving optics includes an optical device that focuses all light pulses received to a spot where a light detector is disposed.
9. The system of any of items 1-8, wherein the light receiving optics includes an optical device that images the scene in the field-of-view in one or two dimension to a light detector array.
10. The system of item 5, wherein the optical modulation device is configured to process a light before the light passes through a beam steering system of the light receiving optics.
11. The system of item 5, wherein the optical modulation device is disposed after light passes through a beam steering system of the light receiving optics.
12. The system of item 5, wherein the optical modulation device is disposed in between different components of a beam steering system of the light receiving optics.
13. The system of item 5, wherein the optical modulation device is disposed in front of a focusing optical device of the light receiving optics, wherein the focusing optical device is an optical device that focuses all light pulses received to a spot where a light detector is disposed.
14. The system of item 5, wherein the optical modulation device is disposed in front of an imaging optical device of the light receiving optics, wherein the imaging optical device is an optical device that images the scene in the field-of-view in one or two dimension to a light detector array.
15. The system of any of items 1-14, wherein an optical beam splitting device is disposed in front of the light receiving optics to divert a portion of the light to a different module as a reference signal.
16. The system of any of items 1-15, wherein the light detection device comprises:
   an optical detector that converts optical signal to electrical signal with an optical-to-electrical amplification factor;
   an electrical signal amplifier that can optionally split the electrical signal output from the said optical detector into two or more independent circuit paths, and amplify the signal in one or more paths.
17. The system of item 16, wherein the optical detector includes at least one of an avalanche photodiode (APD), a one-dimensional APD array, or a two-dimensional APD array.
18. The system of item 16, where the optical detector includes at least one of a CMOS sensor, a CMOS sensor array, a PIN diode, a PIN diode array, a PMT (Photo Multiple Tube), or a PMT array, or an MCP (Micro Channel Plate).
19. The system of item 16, wherein the optical detector includes a micro lens array placed in front of the photo-sensitive device array.
20. The system of item 16, wherein the optical-to-electrical amplification factor of the optical detector implements the modulation function with respect to time.
21. The system of item 16, wherein one of the split electrical signals is used as reference signal.
22. The system of item 16, wherein the amplification factor in one or more circuit paths is configured to implement the modulation function with respect to time.
23. The system of any of items 1-22, wherein the modulation function with respect to time includes at least one of a linear function, a nonlinear function, a monotonic function, or a piece wise monotonic function.
24. The system of any of items 1-23, wherein the signal is integrated over an entire period of the time for the maximum TOF for the designed maximum distance in the field-of-view.
25. The system of any of items 1-24, wherein the signal is integrated over multiple periods of pulse launch.
26. The system of any of items 1-25, wherein the integrated signal is reset one or more times during the integration.
27. The system of any of items 1-26, wherein the signal integration device is implemented using a switching charge amplifier.
28. The system of any of items 1-27, wherein the sampling is performed at the end of an integration period.
29. The system of any of items 1-28, wherein the sampling is performed one or more times during an integration period.
30. The system of any of items 1-29, wherein the electronic computing and data processing unit includes one or more microprocessors, one or multiple FPGAs (field programmable gate array), one or multiple microcontroller units, one or multiple other types electronic computing and data processing devices, or any combination thereof.
31. A method for light detection and ranging (LiDAR), comprising:
   transmitting one or more light pulses through a light emitting optics;
   receiving one or more returned light pulse corresponding to the transmitted one or more light pulses, wherein the returned light pulses are reflected or scattered from an object in a field-of-view of the LiDAR system;
   converting at least a portion of the received one or more returned light pulses into an electrical signal,
   processing the electrical signal, wherein the processing includes amplifying, attenuating, or modulating the converted electrical signal along a signal chain,
      wherein at least one of the receiving, the converting, and the processing further comprises modulating one or more signals with respect to time in accordance with a modulation function;
   integrating the processed electrical signal over a period of time during the light pulse emitting and receiving process to obtain an integrated signal;
   sampling the integrated signal and convert the sampled signal to digital data; and
   determining a distance of a reflection or scattering point on the object in the field-of-view, wherein the said distance is determined based on a time difference between transmitting the one or more light pulses and detecting the one or more returned pulse signals, wherein the time difference is determined by analyzing the sampled signal.
32. The method of item 31, where the signal sampling is performed one or more times during a period of signal integration.
33. The method of item 32, where the sampled integrated signals during one or more integration periods are included to form one or more equations and to be solved together to obtain the TOF and other pulse parameters.
34. The method of any of items 31-33, wherein data for scattering or reflection points close to the reflection or scattering point are used to determine if they belong to a same object.
35. The method of claim 34, where one or more clustering algorithms or segmentation algorithms are used to determine the object in the field-of-view.
36. The method of any of items 31-35, where an intensity of the one or more light pulses is adjusted to a desired level to avoid signal saturation or weak signals.
37. The method of any of items 31-36, where the modulation function is adjusted to a desired level to avoid signal saturation or weak signals.
38. The method of item 33, where one or more outlier detection techniques are used to detect and filter out signals from interference signals from other LiDAR systems, the environment, or the system.
39. A light detection and ranging (LiDAR) system, comprising:
   a first light source configured to transmit one or more light pulses through a light emitting optics;
   a light receiving optics configured to process and modulate, with respect to time, the received light to a light detection device;
   a signal processing device configured to convert and modulate, with respect to time, at least a portion of the received light into an electrical signal;
   a signal integration device configured to integrated the received signals over a period of time during the light pulse emitting and receiving process;
   a signal sampling device configured to sample the integrated signal and convert it to digital data; and
   an electronic computing and data processing unit electrically coupled to first light source and the first light detection device, the electronic computing and data processing unit is configured to determine the distances of the reflection or scattering point on the objects in the field-of-view, wherein the said distances are determined based on the time differences between transmitting the first light pulse and detecting first scattered light pulses determined by analyzing the sampled signals.
40. The system of item 39, wherein the light pulses have one or more pulse widths of less than 1 nanosecond, 1 to 5 nanoseconds, or 5 to 200 nanoseconds.
41. The system of any of items 39-40, wherein the light emitting optics comprises a beam steering system that steers the emitting light in one or two directions.
42. The system of any of items 39-41, wherein the light emitting optics diverge the light coming out of the light source to an angle of 1 to 270 degrees in the field-of-view.
43. The system of any of items 39-42, wherein the light receiving optics includes an optical modulation device that modulates the intensity or polarization state or phase of any one or combination of two or more of the said properties of the light passing through it with respect to time.
44. The system of item 41, wherein the light receiving optics includes the beam steering system.
45. The system of item 41, wherein the light receiving optics includes a second beam steering system that is physically different from the beam steering system, and the second beam steering system steers the received light beam in substantially synchronous manner in the reverse direction as the beam steering system.
46. The system of any of items 39-45, wherein the light receiving optics includes an optical device that focuses all light pulses received to a spot where a light detector is disposed.
47. The system of any of items 39-46, wherein the light receiving optics includes an optical device that images the scene in the field-of-view in one or two dimension to a light detector array.
48. The system of item 43, wherein the optical modulation device is disposed in front of the beam steering system in item 44 or item 45.
49. The system of item 43, wherein the optical modulation device is disposed after light passes through the beam steering system in item 44 or item 45.
50. The system of item 43, wherein the optical modulation device is disposed in between different components of the beam steering system in item 44 or item 45.
51. The system of item 43, wherein the optical modulation device is disposed in front of the focusing optical device in item 46.
52. The system of item 43, wherein the optical modulation device is disposed in front of the imaging optical device in item 47.
53. The system of any of items 39-52, wherein an optical beam splitting device is disposed in front of the light receiving optics to divert a portion of the light to a different module as a reference signal.
54. The system of any of items 39-53, wherein the light signal processing device comprises:
   an optical detector that converts optical signal to electrical signal with an optical-to-electrical amplification factor;
   an electrical signal amplifier that can optionally split the electrical signal output from the said optical detector into two or more independent circuit paths, and amplify the signal in one or more paths.
55. The system of item 54, wherein the optical detector includes at least one of an avalanche photodiode (APD), a one-dimensional APD array, or a two-dimensional APD array.
56. The system of item 54, where the optical detector includes at least one of a CMOS sensor, a CMOS sensor array, a PIN diode, a PIN diode array, a PMT (Photo Multiple Tube), or a PMT array, or an MCP (Micro Channel Plate).
57. The system of item 54, wherein the optical detector includes a micro lens array being placed in front of the photo-sensitive device array.
58. The system of item 54, wherein the optical-to-electrical amplification factor of the optical detector implements the modulation function with respect to time in item 39.
59. The system of item 54, wherein in the electrical amplifier, one of the split electrical signals is used as reference signal.
60. The system of item 54, wherein the amplification factor in one or more circuit paths can implement the modulation function with respect to time in item 39.
61. The system of any of items 39-60, wherein the modulation function with respect to time include at least one of a linear function, a nonlinear function, a monotonic function, or a piece wise monotonic function.
62. The system of any of items 39-61, wherein the signal is integrated over entire period of the time for the maximum TOF for the designed maximum distance in the field-of-view.
63. The system of any of items 39-62, wherein the signal is integrated over multiple periods of pulse launch.
64. The system of any of items 39-63, wherein the integrated signal is reset one or multiple times during the integration.
65. The system of any of items 39-64, wherein the device is implemented using a switching charge amplifier.
66. The system of any of items 39-65, wherein the sampling is performed at the end of the integration period.
67. The system of any of items 39-66, wherein the sampling is performed one or multiple times during the integration period.
68. The system of any of items 39-67, wherein the electronic computing and data processing unit is one or multiple microprocessors, one or multiple FPGAs (field programmable gate array), one or multiple microcontroller units, one or multiple other types electronic computing and data processing devices, or the combination of the said devices.
69. A method for light detection and ranging (LiDAR), comprising:
   transmitting one or more light pulses through a light emitting optics;
   processing and modulating with respect to time the received light to a light detection device;
   converting and modulating with respect to time all or a portion of the received light into electrical signal;
   integrating the received signals over a period of time during the light pulse emitting and receiving process;
   sampling the integrated signal and convert it to digital data; and
   determining the distances of the reflection or scattering point on the objects in the field-of-view, wherein the said distances are determined based on the time differences between transmitting the first light pulse and detecting first scattered light pulses determined by analyzing the sampled signals.
70. The method of item 69, where the signal sampling is performed one or multiple times during the period of signal integration.
71. The method of any of items 69-70, where the sampled integrated signals during one or multiple integration periods are included to form one or multiple equations and to be solved together to obtain the TOF and other pulse parameters.
72. The method of any of items 69-71, where the data for scattering or reflection points close to the current point are used together to determine if they belong to the same object and help determine if the signal is saturated or too weak.
73. The method in item 72, where clustering algorithms or segmentation algorithms are used to determine the objects in the field-of-view.
74. The method of any of items 69-73, where the light pulse intensity is adjusted to desired level to avoid the situation of signal saturation or being too weak.
75. The method of any of items 69-74, where the modulation function in item 59 is adjusted to desired level to avoid the situation of signal saturation or being too weak.
76. The method of any of items 69-75, where the adjustment methods in item 74 and in item 75 can be combined to avoid the situation of signal saturation or being too weak.
77. The method in item 71, where outlier detection techniques are used to detect and filter out signals from interference signals from other LiDAR systems or the environment or the system.

What is claimed is:

1. A light detection and ranging (LiDAR) system, comprising:
a first light source configured to transmit one or more light pulses through a light emitting optics;
a light receiving optics configured to receive one or more returned light pulses corresponding to the transmitted one or more light pulses, wherein the returned light pulses are reflected or scattered from an object in a field-of-view of the LiDAR system;
a light detection device configured to convert at least a portion of the received one or more returned light pulses into an electrical signal;
a signal processing device configured to process the converted electrical signal, wherein the processing includes amplifying, attenuating or modulating the converted electrical signal,
wherein at least one of the signal processing device, light receiving optics and the light detection device is further configured to modulate one or more signals with respect to time in accordance with a modulation function;
a signal integration device configured to integrate the processed electrical signal over a period of time during the light pulse emitting and receiving process to obtain an integrated signal;
a signal sampling device configured to sample the integrated signal and convert the sampled signal to digital data; and
an electronic computing and data processing unit electrically coupled to the first light source and a light detection device, the electronic computing and data processing unit is configured to determine a distance of a reflection or scattering point on the object in the field-of-view, wherein the said distance is determined based on a time difference between transmitting the one or more light pulses and detecting the returned one or more pulse signals, and wherein the time difference is determined by analyzing the sampled signal.

2. The system of claim 1, wherein the one or more light pulses have one or more pulse widths of less than 1 nanosecond, 1 to 5 nanoseconds, or 5 to 200 nanoseconds.

3. The system of claim 1, wherein the light emitting optics comprises a beam steering system that steers an emitting light in one or two directions.

4. The system of claim 1, wherein the light emitting optics diverge a light coming out of the light source to an angle of 1 to 270 degrees in the field-of-view.

5. The system of claim 1, wherein the light receiving optics includes an optical modulation device that modulates the intensity or polarization state or phase of any one or combination of two or more of the said properties of the light passing through it with respect to time.

6. The system of claim 3, wherein the light receiving optics includes the beam steering system.

7. The system of claim 3, wherein the light receiving optics includes a second beam steering system that is physically different from the beam steering system, and the second beam steering system steers the received light beam in a substantially synchronous manner in the reverse direction as the beam steering system.

8. The system of claim 1, wherein the light receiving optics includes an optical device that focuses all light pulses received to a spot where a light detector is disposed.

9. The system of claim 1, wherein the light receiving optics includes an optical device that images the scene in the field-of-view in one or two dimension to a light detector array.

10. The system of claim 5, wherein the optical modulation device is configured to process a light before the light passes through a beam steering system of the light receiving optics.

11. The system of claim 5, wherein the optical modulation device is disposed after light passes through a beam steering system of the light receiving optics.

12. The system of claim 5, wherein the optical modulation device is disposed in between different components of a beam steering system of the light receiving optics.

13. The system of claim 5, wherein the optical modulation device is disposed in front of a focusing optical device of the light receiving optics, wherein the focusing optical device is an optical device that focuses all light pulses received to a spot where a light detector is disposed.

14. The system of claim 5, wherein the optical modulation device is disposed in front of an imaging optical device of the light receiving optics, wherein the imaging optical device is an optical device that images the scene in the field-of-view in one or two dimension to a light detector array.

15. The system of claim 1, wherein an optical beam splitting device is disposed in front of the light receiving optics to divert a portion of the light to a different module as a reference signal.

16. The system of claim 1, wherein the light detection device comprises:
an optical detector that converts optical signal to electrical signal with an optical-to-electrical amplification factor;
an electrical signal amplifier that can optionally split the electrical signal output from the said optical detector into two or more independent circuit paths, and amplify the signal in one or more paths.

17. The system of claim 16, wherein the optical detector includes at least one of an avalanche photodiode (APD), a one-dimensional APD array, or a two-dimensional APD array.

18. The system of claim 16, where the optical detector includes at least one of a CMOS sensor, a CMOS sensor array, a PIN diode, a PIN diode array, a PMT (Photo Multiple Tube), or a PMT array, or an MCP (Micro Channel Plate).

19. The system of claim 16, wherein the optical detector includes a micro lens array placed in front of the photo-sensitive device array.

20. The system of claim 16, wherein the optical-to-electrical amplification factor of the optical detector implements the modulation function with respect to time.

21. The system of claim 16, wherein one of the split electrical signals is used as reference signal.

22. The system of claim 16, wherein the amplification factor in one or more circuit paths is configured to implement the modulation function with respect to time.

23. The system of claim 1, wherein the modulation function with respect to time includes at least one of a linear function, a nonlinear function, a monotonic function, or a piece wise monotonic function.

24. The system of claim 1, wherein the signal is integrated over an entire period of the time for the maximum TOF for the designed maximum distance in the field-of-view.

25. The system of claim 1, wherein the signal is integrated over multiple periods of pulse launch.

26. The system of claim 1, wherein the integrated signal is reset one or more times during the integration.

27. The system of claim 1, wherein the signal integration device is implemented using a switching charge amplifier.

28. The system of claim 1, wherein the sampling is performed at the end of an integration period.

29. The system of claim 1, wherein the sampling is performed one or more times during an integration period.

30. The system in claim 1, wherein the electronic computing and data processing unit includes one or more microprocessors, one or multiple FPGAs (field programmable gate array), one or multiple microcontroller units, one or multiple other types electronic computing and data processing devices, or any combination thereof.

31. A method for light detection and ranging (LiDAR), comprising:
transmitting one or more light pulses through a light emitting optics;
receiving one or more returned light pulse corresponding to the transmitted one or more light pulses, wherein the returned light pulses are reflected or scattered from an object in a field-of-view of the LiDAR system;
converting at least a portion of the received one or more returned light pulses into an electrical signal,
processing the electrical signal, wherein the processing includes amplifying, attenuating, or modulating the converted electrical signal along a signal chain,
wherein at least one of the receiving, the converting, and the processing further comprises modulating one or more signals with respect to time in accordance with a modulation function;
integrating the processed electrical signal over a period of time during the light pulse emitting and receiving process to obtain an integrated signal;
sampling the integrated signal and convert the sampled signal to digital data; and
determining a distance of a reflection or scattering point on the object in the field-of-view, wherein the said distance is determined based on a time difference between transmitting the one or more light pulses and detecting the one or more returned pulse signals, wherein the time difference is determined by analyzing the sampled signal.

32. The method in claim 31, where the signal sampling is performed one or more times during a period of signal integration.

33. The method in claim 32, where the sampled integrated signals during one or more integration periods are included to form one or more equations and to be solved together to obtain the TOF and other pulse parameters.

34. The method in claim 31, wherein data for scattering or reflection points close to the reflection or scattering point are used to determine if they belong to a same object.

35. The method in claim 34, where one or more clustering algorithms or segmentation algorithms are used to determine the object in the field-of-view.

36. The method in claim 31, where an intensity of the one or more light pulses is adjusted to a desired level to avoid signal saturation or weak signals.

37. The method in claim 31, where the modulation function is adjusted to a desired level to avoid signal saturation or weak signals.

38. The method in claim 33, where one or more outlier detection techniques are used to detect and filter out signals from interference signals from other LiDAR systems, the environment, or the system.
